(19) United States
(12) Patent Application Publication
(10) Pub. No.: US 2025/0370435 A1
(43) Pub. Date: Dec. 4, 2025

(54) IMPROVED SYSTEMS, METHODS, AND COMPUTER PROGRAM PRODUCTS FOR AUTOMATION OF PLC CODE PROGRAMMING AND HMI

(71) Applicant: CODIQ 4.0 LTD, Caesarea (IL)

(72) Inventors: Javier Bruno FARKAS, Nahariyya (IL); Igal LEBEDEV, Beit Yehoshua (IL); Oleg KANDILIYOV, Harish (IL)

(73) Assignee: CODIQ 4.0 LTD, Caesarea (IL)

(21) Appl. No.: 18/876,929

(22) PCT Filed: Jun. 22, 2023
(86) PCT No.: PCT/IL2023/050649

§ 371 Date: Dec. 19, 2024

Related U.S. Application Data
(60) Provisional application No. 63/354,430, filed on Jun. 22, 2022.

(51) Int. Cl. G05B 19/418; G06Q 50/04

(52) U.S. Cl. CPC G05B 19/41835; G06Q 50/04; G05B 2219/31001

(57) ABSTRACT

System, product and method for controlling an industrial process in a factory, the industrial process involving a flow of material, the method comprising using a hardware processor for accepting a definition and/or information regarding a route extending from a source (e.g., raw material tank) to a destination (e.g., filler), along which the material flows and/or, accordingly, automatically activating and/or de-activating material flow along the route.

### REFERENCE TO CO-PENDING APPLICATIONS

Priority is claimed from U.S. Provisional Patent Application No. 63/354,430 entitled “Improved Systems, Methods And Computer Program Products For Automation Of Plc Code Programming And HMI” and filed Jun. 22, 2022, the disclosure of which application/s is hereby incorporated by reference.

### FIELD OF THIS DISCLOSURE

The present invention relates generally to manufacturing process engineering, and more particularly to systems and methods for process manufacturing.

### BACKGROUND FOR THIS DISCLOSURE

RockwellAutomation.com provides “Programming tools and advanced software applications (which) include remote access and data analysis to accelerate development and improve efficiency”. Allen-Bradley is a tradename for automated components and integrated control systems for safety, sensing, industrial control, power control, and motion control. FactoryTalk refers to software that supports an ecosystem of advanced industrial applications, including IoT, system design, operations, plant maintenance, and analytics.

FactoryTalk View SE is described as “an integral element of the Rockwell Automation visualization solution” and as enabling its users “to take advantage of mobility, virtualization, and other new technologies, meeting HMI challenges in process, batch, and discrete applications”.

Studio 5000 Logix Designer® is software for managing the Allen-Bradley Logix 5000™ family of controllers and related control system.

In “How Industrial Networks Operate”, Eric Knapp describes that “Human machine interfaces (HMIs) are used as an operator control panel to PLCs, RTUs, and in some cases directly to IEDs . . . HMIs allow operators to start and stop cycles, adjust set points, and perform other functions required to adjust and interact with a control process . . . The HMI, in turn, interacts with one or more PLCs and/or RTUs, typically using industrial protocols such as OLE for Process Control (OPC) or fieldbus protocols such as Modbus.”

W. Bolton, in Control Systems, 2002, describes that a programmable logic controller (PLC) is a “microprocessor-based controller that uses a programmable memory to store instructions and is designed to be operated by engineers with . . . limited knowledge of computers and computing languages”.

Eric Knapp, in Industrial Network Security, 2011, describes Ladder Logic: “PLCs often use “ladder logic,” a simplistic programming language that is well suited for industrial applications . . . A path is traced on the left side, across “rungs” consisting of various inputs. If an input relay is “true” the path continues, and if it is “false” it does not. If the path to the right side completes (there is a complete “true” path across the ladder), the ladder is complete and the output coil will be set to “true” or “energized.” If no path can be traced, then the output remains “false,” and the relay remains “de-energized.”

Eric Knapp, in Industrial Network Security, 2011 describes that “Industrial Network Protocols are often referred to generically as SCADA and/or fieldbus protocols. SCADA protocols are primarily used for the communication of supervisory systems, whereas fieldbus protocols are used for the communication of industrial, automated control systems (ICS or IACS). Modbus is the oldest and perhaps the most widely deployed industrial control communications protocol.”

This online source https://www.inductiveautomation.com/blog/the-benefits-of-integrating-your-mes-system-with-scada#:˜:text=SCADA%20(supervisory%20control%20and%20data,tasks%20at%20the%20office%20level describes that: “The roles of MES and SCADA can often overlap, but generally an MES system facilitates the transformation of raw materials into finished goods in real time, deals with overall equipment effectiveness (OEE)/downtime, and may include other functions such as SPC (statistical process control), production and resource scheduling, tracking and tracing products and materials, dispatching production tasks and work instructions, managing preventive maintenance, analyzing performance, and more. . . . Ignition SCADA modules provide features such as: Real-Time Status Control, Alarming, Reporting, Data Acquisition, Scripting, Scheduling, MES, and Mobile support.”

Published U.S. Ser. No. 17/283,676 to Javier Bruno Farkas (publication no. US 2021/0382450) describes computerized programing of a controller of an industrial system.

Automation systems are known e.g., Deltav, as described here: https://www.emerson.com/en-us/automation/deltav.

Many fillers are known in the art, e.g., as described here: https://en.wikipedia.org/wiki/Filler (packaging).

ISA-88 is a standard addressing batch process control which describes equipment and procedures.

The disclosures of all publications and patent documents mentioned in the specification, and of the publications and patent documents cited therein, directly or indirectly, are hereby incorporated by reference, other than subject matter disclaimers or disavowals. If the incorporated material is inconsistent with the express disclosure herein, the interpretation is that the express disclosure herein describes certain embodiments, whereas the incorporated material describes other embodiments. Definition/s within the incorporated material may be regarded as one possible definition for the term/s in question.

### SUMMARY OF CERTAIN EMBODIMENTS

Certain embodiments of the present invention seek to provide circuitry typically comprising at least one processor in communication with at least one memory, with instructions stored in such memory executed by the processor to provide functionalities which are described herein in detail. Any functionality described herein may be firmware-implemented or processor-implemented, as appropriate.

Certain embodiments define groups of modules in a factory, and defines their order of energization and/or de-energization.

Certain embodiments are configured for providing PLC code to control modules such as engines along a route.

It is appreciated that the embodiments herein are applicable broadly, for various industries e.g., including food & beverage manufacturing, water technology, energy, pharma, and cosmetics industries.

The embodiments herein are advantageous inter alia to facilitate the move to, or use of, a Smart Factory paradigm, by manufacturers and system integrators, where the paradigm typically includes connected machines, devices, and production systems, and typically continuously collects and shares data through the connected machines, devices, and production systems, and typically facilitates production which is more agile, efficient, and/or produces less waste, and/or relies less on error-prone human involvement, e.g., by improving planning of optimized processes.

It is appreciated that “energizing” as used herein is not necessarily equivalent to opening (a valve e.g.) and “de-energizing” is not necessarily equivalent to closing (a valve e.g.).

The relation depends on the type of valve, such that, for some valves, “energizing” comprises closing (a valve e.g.) and “de-energizing” comprises opening. In the disclosure herein, references to “energizing” (or to “de-energizing”) may each be replaced by either “opening” or closing”, depending on the context (on the valve e.g.). Generally, engines, if active, drive material flow, open valves allow material flow, and closed valves block material flow.

Energizing or activating (these terms may be interchanged herein, unless the opposite is apparent) may for example include turning a motor or other engine on, or opening a valve which is currently closed.

It is appreciated that any reference herein to, or recitation of, an operation being performed is, e.g. if the operation is performed at least partly in software, intended to include both an embodiment where the operation is performed in its entirety by a server A, and also to include any type of “outsourcing” or “cloud” embodiments in which the operation, or portions thereof, is or are performed by a remote processor P (or several such), which may be deployed off-shore or “on a cloud”, and an output of the operation is then communicated to, e.g. over a suitable computer network, and used by, server A. Analogously, the remote processor P may not, itself, perform all of the operations, and, instead, the remote processor P itself may receive output/s of portion/s of the operation from yet another processor/s P′, may be deployed off-shore relative to P, or “on a cloud”, and so forth.

The present invention typically includes at least the following embodiments:

Embodiment 1. A method for controlling an industrial process in a factory, the industrial process involving a flow of material, the method comprising using a hardware processor for:
accepting a definition and/or information regarding a route extending from a source (e.g., raw material tank) to a destination (e.g., filler), along which the material flows;
and, accordingly, automatically activating and/or de-activating material flow along the route.

In the present specification, “source” and “starting point” may be interchanged unless clearly unsuitable in context (e.g. not in the context of “source code”).

Embodiment 2. A method according to any of the preceding embodiments wherein the automatically activating and de-activating comprises: grouping the elements into group/s (aka sequencing groups) thereby to facilitate route activation and deactivation; and automatically generating source code (e.g. PLC code) for controllers (e.g., Programmable Logic Controllers) which control sequencing groups of elements (e.g. valves, conveyor transfers, pumps) along the route, wherein the source code orchestrates or controls the route (e.g., causing material to flow along the route), wherein the source code, when executed by the controllers, is configured to:
a. close, or ensure closure of, all controlled elements, e.g., valves (“junction valves”), conveyor transfers along the route which enable material to flow in any direction other than along the route; and
b. open valves and shifters downstream of a first group of engines, and then, subsequently, activate all valves and conveyor transfers between the source and the first group of engines, and then, subsequently, activate the first group of engines wherein within each sequencing group, wherein engines are activated in an upstream direction such that given a first engine in the group which is upstream of a second engine in the group, the first engine is activated only after the second engine is activated.

It is appreciated that:
a. material may flow through a route even without an engine (even if the route includes no engines), e.g., due to gravity through valves and/or Silo's gates.
b. Typically, the most upstream valve (e.g., outlet valve of a processing unit or tank e.g., source) is the last valve to open.
c. The generated sequencing code typically covers arbitration and/or interlocking and/or alarming per controlled element e.g., as required by industry best practices.
d. elements may include valves, engines, shifters, sensors, all of which can be controlled and/or measured.
e. controlled elements or control modules are intended to include elements which can be controlled and/or measured using automation (as opposed to manual elements aka manually controlled elements which are hand-operated)
f. engines: (e.g. conveyers, motors, pumps) drive material flow along certain routes; it is appreciated that other routes have no engines yet material flow results from gravity or other causes.
g. a route element is intended to include an element that is part of a route. Not all elements are necessarily included in a route; also, a single element may be included in more than one route. These may be grouped into sequencing groups for route activation and deactivation.

Embodiment 3. A method according to any of the preceding embodiments where multiple engines exist along the route including a last engine which is downstream of all other engines along the route and where a sequencing group downstream of the last engine is activated first, then a sequencing group upstream of the first engine, and only then a sequencing group that includes the engines.

The sequencing group that includes the engines may also include valves, conveyor transfer etc. When this is the case, within this group, valves and conveyor transfers are activated in upstream order e.g. a first valve which is upstream of a second valve is activated only after the second valve is activated, and then engines in the group are activated, also in upstream order. Typically, the most upstream valve in the group (e.g., outlet valve of a tank or processing unit) is the last valve to open.

Embodiment 4. A method according to any of the preceding embodiments where deactivation of a route occurs in an order which is reversed relative to the order in which activation of the route occurs, including:
deactivating elements within each group in an order which is reversed relative to an order in which the elements within the group were activated such that an element x in a Group A which was activated before an element y in the Group A, is deactivated after element y is deactivated, and
deactivating groups in an order which is reversed relative to an order in which the groups were activated such that a Group A, which was activated before Group B, is deactivated after Group B is deactivated.

Embodiment 5. A method according to any of the preceding embodiments wherein the source code provides a sequencing order of all valves along the route.

Embodiment 6. A method according to any of the preceding embodiments wherein the source code provides a sequencing order of all pumps along the route.

Embodiment 7. A method according to any of the preceding embodiments wherein the source code provides a sequencing order of all motors along the route.

Embodiment 8. A method according to any of the preceding embodiments wherein the source code provides a sequencing order of all conveyers along the route.

Embodiment 9. A method according to any of the preceding embodiments utilizing start criteria and/or stop criteria which are static.

Embodiment 10. A method according to any of the preceding embodiments wherein material flows along the route through pipes and/or via conveyers.

Embodiment 11. A method according to any of the preceding embodiments wherein at least one of the start criteria and/or stop criteria which are static comprises a duration criterion.

Embodiment 12. A method according to any of the preceding embodiments wherein the accepting the definition includes automated analysis configured to identify any engines (e.g., conveyers, motors, pumps) that drive material flow along the route.

Embodiment 13. A method according to any of the preceding embodiments wherein the source comprises a raw material tank, and the destination comprises a filler.

Embodiment 14. A method according to any of the preceding embodiments wherein the engines are taken from a group comprising at least conveyers, motors, and pumps.

Embodiment 15. A method according to any of the preceding embodiments wherein the method includes automated analysis of all controlled elements along the route; and the controlled elements' sequential arrangement along the route, to determine a set of control actions and status verifications to yield safe activation and/or safe deactivation of material flow through the route.

Embodiment 16. A method according to any of the preceding embodiments, and also comprising allowing authorized users, designated from among factory personnel or system integrators, to make modifications to specific routing and sequencing parameters to optimize or recover production issues without PLC downtime.

For example, a sequencing timer may be tuned or set to allow extra time for a valve open sequence to complete before starting a pump.

Embodiment 17. A method according to any of the preceding embodiments wherein the given operation comprises in-unit operation taking place within a single element participating in the given operation.

Embodiment 18. A method according to any of the preceding embodiments wherein the code is configured for issuing commands which activate and de-activate each element along the route, typically while taking care of any alarm being flagged (typically all commands necessary).

Embodiment 19. A method according to any of the preceding embodiments wherein the code is configured to cause the route's status, including operational parameters' real time present values, to be displayed to an operator.

Embodiment 20. A method according to any of the preceding embodiments wherein all of the junction valves are verified as closed simultaneously.

Embodiment 21. A method according to any of the preceding embodiments wherein all engines in the first group are activated simultaneously.

Embodiment 22. A hardware processor configured to perform any method herein.

Embodiment 23. A computer program product, comprising a non-transitory tangible computer readable medium having computer readable program code embodied therein, the computer readable program code adapted to be executed to implement a method for controlling an industrial process in a factory, the industrial process involving a flow of material, the method comprising: accepting a definition and/or information regarding a route extending from a source (e.g., raw material tank) to a destination (e.g., filler), along which the material flows; and/or, accordingly, automatically activating and/or de-activating material flow along the route.

Also provided, excluding signals, is a computer program comprising computer program code means for performing any of the methods shown and described herein when the program is run on at least one computer; and a computer program product, comprising a typically non-transitory computer-usable or-readable medium e.g. non-transitory computer-usable or -readable storage medium, typically tangible, having a computer readable program code embodied therein, the computer readable program code adapted to be executed to implement any or all of the methods shown and described herein. The operations in accordance with the teachings herein may be performed by at least one computer specially constructed for the desired purposes, or a general purpose computer specially configured for the desired purpose by at least one computer program stored in a typically non-transitory computer readable storage medium. The term “non-transitory” is used herein to exclude transitory, propagating signals, or waves, but to otherwise include any volatile or non-volatile computer memory technology suitable to the application.

Any suitable processor/s, display and input means may be used to process, display e.g. on a computer screen or other computer output device, store, and accept information such as information used by or generated by any of the methods and apparatus shown and described herein; the above processor/s, display and input means including computer programs, in accordance with all or any subset of the embodiments of the present invention. Any or all functionalities of the invention shown and described herein, such as but not limited to operations within flowcharts, may be performed by any one or more of at least one conventional personal computer processor, workstation, or other programmable device or computer or electronic computing device or processor, either general-purpose or specifically constructed, used for processing; a computer display screen and/or printer and/or speaker for displaying; machine-readable memory such as flash drives, optical disks, CDROMs, DVDs, BluRays, magnetic-optical discs or other discs; RAMs, ROMs, EPROMS, EEPROMs, magnetic or optical or other cards, for storing, and keyboard or mouse for accepting. Modules illustrated and described herein may include any one or combination or plurality of a server, a data processor, a memory/computer storage, a communication interface (wireless (e.g. BLE) or wired (e.g. USB)), and a computer program stored in memory/computer storage.

The term “process” as used above is intended to include any type of computation or manipulation or transformation of data represented as physical, e.g., electronic, phenomena which may occur or reside e.g., within registers and/or memories of at least one computer or processor. Use of nouns in singular form is not intended to be limiting; thus, the term processor is intended to include a plurality of processing units which may be distributed or remote, the term server is intended to include plural typically interconnected modules running on plural respective servers, and so forth.

The above devices may communicate via any conventional wired or wireless digital communication means, e.g., via a wired or cellular telephone network, or a computer network such as the Internet.

The apparatus of the present invention may include, according to certain embodiments of the invention, machine readable memory containing or otherwise storing a program of instructions which, when executed by the machine, implements all or any subset of the apparatus, methods, features, and functionalities of the invention shown and described herein. Alternatively, or in addition, the apparatus of the present invention may include, according to certain embodiments of the invention, a program as above which may be written in any conventional programming language, and optionally a machine for executing the program, such as but not limited to a general-purpose computer which may optionally be configured or activated in accordance with the teachings of the present invention. Any of the teachings incorporated herein may, wherever suitable, operate on signals representative of physical objects or substances.

The embodiments referred to above, and other embodiments, are described in detail in the next section.

Any trademark occurring in the text or drawings is the property of its owner and occurs herein merely to explain or illustrate one example of how an embodiment of the invention may be implemented.

Unless stated otherwise, terms such as, “processing”, “computing”, “estimating”, “selecting”, “ranking”, “grading”, “calculating”, “determining”, “generating”, “reassessing”, “classifying”, “generating”, “producing”, “stereo-matching”, “registering”, “detecting”, “associating”, “superimposing”, “obtaining”, “providing”, “accessing”, “setting” or the like, refer to the action and/or processes of at least one computer/s or computing system/s, or processor/s or similar electronic computing device/s or circuitry, that manipulate and/or transform data which may be represented as physical, such as electronic, quantities e.g. within the computing system's registers and/or memories, and/or may be provided on-the-fly, into other data which may be similarly represented as physical quantities within the computing system's memories, registers, or other such information storage, transmission or display devices, or may be provided to external factors e.g., via a suitable data network. The term “computer” should be broadly construed to cover any kind of electronic device with data processing capabilities, including, by way of non-limiting example, personal computers, servers, embedded cores, computing systems, communication devices, processors (e.g. digital signal processor (DSP), microcontrollers, field programmable gate array (FPGA), application specific integrated circuit (ASIC), etc.) and other electronic computing devices. Any reference to a computer, controller, or processor is intended to include one or more hardware devices e.g., chips, which may be co-located or remote from one another. Any controller or processor may, for example, comprise at least one CPU, DSP, FPGA or ASIC, suitably configured in accordance with the logic and functionalities described herein.

Any feature or logic or functionality described herein may be implemented by processor/s or controller/s configured as per the described feature or logic or functionality, even if the processor/s or controller/s are not specifically illustrated for simplicity. The controller or processor may be implemented in hardware, e.g., using one or more Application-Specific Integrated Circuits (ASICs) or Field-Programmable Gate Arrays (FPGAs), or may comprise a microprocessor that runs suitable software, or a combination of hardware and software elements.

The present invention may be described, merely for clarity, in terms of terminology specific to, or references to, particular programming languages, operating systems, browsers, system versions, individual products, protocols and the like. It will be appreciated that this terminology or such reference/s is intended to convey general principles of operation clearly and briefly, by way of example, and is not intended to limit the scope of the invention solely to a particular programming language, operating system, browser, system version, or individual product or protocol. Nonetheless, the disclosure of the standard or other professional literature defining the programming language, operating system, browser, system version, or individual product or protocol in question, is incorporated by reference herein in its entirety.

Elements separately listed herein need not be distinct components, and alternatively may be the same structure. A statement that an element or feature may exist is intended to include (a) embodiments in which the element or feature exists; (b) embodiments in which the element or feature does not exist; and (c) embodiments in which the element or feature exist selectably, e.g., a user may configure or select whether the element or feature does or does not exist.

Any suitable input device, such as but not limited to a sensor, may be used to generate or otherwise provide information received by the apparatus and methods shown and described herein. Any suitable output device or display may be used to display or output information generated by the apparatus and methods shown and described herein. Any suitable processor/s may be employed to compute or generate or route, or otherwise manipulate or process information as described herein and/or to perform functionalities described herein and/or to implement any engine, interface or other system illustrated or described herein. Any suitable computerized data storage, e.g., computer memory, may be used to store information received by or generated by the systems shown and described herein. Functionalities shown and described herein may be divided between a server computer and a plurality of client computers. These or any other computerized components shown and described herein may communicate between themselves via a suitable computer network.

The system shown and described herein may include user interface/s e.g. as described herein which may for example include all or any subset of an interactive voice response interface, automated response tool, speech-to-text transcription system, automated digital or electronic interface having interactive visual components, web portal, visual interface loaded as web page/s or screen/s from server/s via communication network/s to a web browser or other application downloaded onto a user's device, automated speech-to-text conversion tool, including a front-end interface portion thereof and back-end logic interacting therewith. Thus the term user interface or “UI” as used herein includes also the underlying logic which controls the data presented to the user, e.g., by the system display and receives and processes and/or provides to other modules herein, data entered by a user e.g., using her or his workstation/device.

### BRIEF DESCRIPTION OF THE DRAWINGS

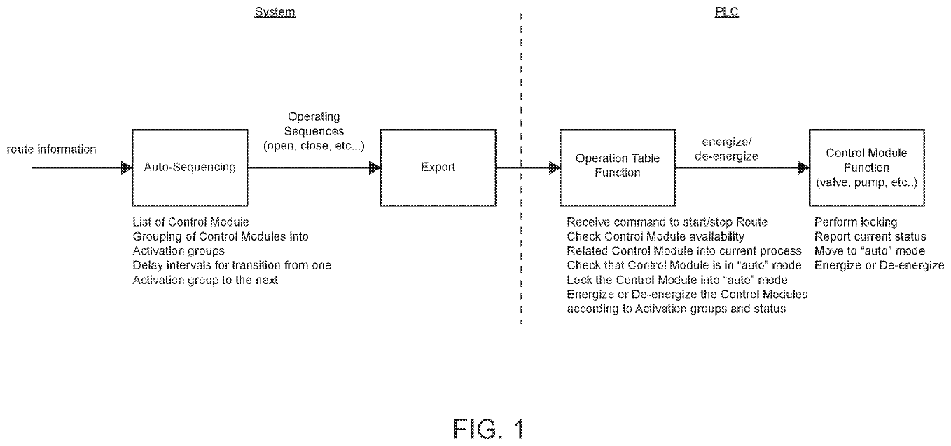

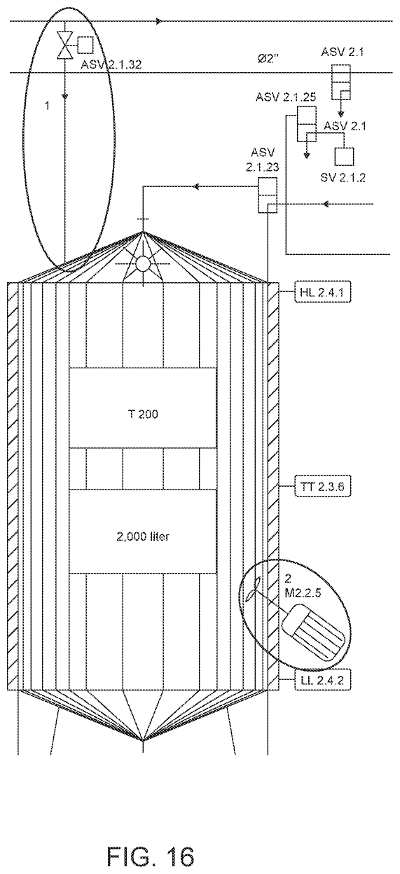

Example embodiments are illustrated in FIGS. 1-20 herein.

In the block diagrams, arrows between modules may be implemented as APIs, and any suitable technology may be used for interconnecting functional components or modules illustrated herein in a suitable sequence or order e.g. via a suitable API/Interface. For example, state of the art tools may be employed, such as but not limited to Apache Thrift and

Avro which provide remote call support. Or, a standard communication protocol may be employed, such as but not limited to HTTP or MQTT, and may be combined with a standard data format, such as but not limited to JSON or XML. According to one embodiment, one of the modules may share a secure API with another. Communication between modules may comply with any customized protocol, or customized query language, or may comply with any conventional query language or protocol.

Methods and systems included in the scope of the present invention may include any subset or all of the functional blocks shown in the specifically illustrated implementations by way of example, in any suitable order e.g. as shown. Flows may include all or any subset of the illustrated operations, suitably ordered e.g., as shown. Tables herein may include all or any subset of the fields and/or records and/or cells and/or rows and/or columns described.

Computational, functional or logical components described and illustrated herein can be implemented in various forms, for example, as hardware circuits, such as but not limited to custom VLSI circuits or gate arrays or programmable hardware devices such as but not limited to FPGAs, or as software program code stored on at least one tangible or intangible computer readable medium and executable by at least one processor, or any suitable combination thereof. A specific functional component may be formed by one particular sequence of software code, or by a plurality of such, which collectively act or behave or act as described herein with reference to the functional component in question. For example, the component may be distributed over several code sequences such as but not limited to objects, procedures, functions, routines and programs, and may originate from several computer files which typically operate synergistically.

Each functionality or method herein may be implemented in software (e.g. for execution on suitable processing hardware such as a microprocessor or digital signal processor), firmware, hardware (using any conventional hardware technology such as Integrated Circuit technology), or any combination thereof.

Functionality or operations stipulated as being software-implemented may alternatively be wholly or fully implemented by an equivalent hardware or firmware module, and vice-versa. Firmware implementing functionality described herein, if provided, may be held in any suitable memory device, and a suitable processing unit (aka processor) may be configured for executing firmware code. Alternatively, certain embodiments described herein may be implemented partly or exclusively in hardware, in which case all or any subset of the variables, parameters, and computations described herein may be in hardware.

Any module or functionality described herein may comprise a suitably configured hardware component or circuitry. Alternatively or in addition, modules or functionality described herein may be performed by a general purpose computer, or more generally by a suitable microprocessor, configured in accordance with methods shown and described herein, or any suitable subset, in any suitable order, of the operations included in such methods, or in accordance with methods known in the art.

Any logical functionality described herein may be implemented as a real time application, if and as appropriate, and which may employ any suitable architectural option, such as but not limited to FPGA, ASIC, or DSP, or any suitable combination thereof.

Any hardware component mentioned herein may in fact include either one or more hardware devices e.g., chips, which may be co-located or remote from one another.

Any method described herein is intended to include within the scope of the embodiments of the present invention also any software or computer program performing all or any subset of the method's operations, including a mobile application, platform, or operating system e.g., as stored in a medium, as well as combining the computer program with a hardware device to perform all or any subset of the operations of the method.

Data can be stored on one or more tangible or intangible computer readable media stored at one or more different locations, different network nodes or different storage devices at a single node or location.

It is appreciated that any computer data storage technology, including any type of storage or memory and any type of computer components and recording media that retain digital data used for computing for an interval of time, and any type of information retention technology, may be used to store the various data provided and employed herein. Suitable computer data storage or information retention apparatus may include apparatus which is primary, secondary, tertiary, or off-line; which is of any type or level or amount or category of volatility, differentiation, mutability, accessibility, addressability, capacity, performance and energy use; and which is based on any suitable technologies such as semiconductor, magnetic, optical, paper, and others.

### DETAILED DESCRIPTION OF CERTAIN EMBODIMENTS

FIG. 1 is a simplified block diagram illustration of a system according to certain embodiments; the system receives route information e.g., names of all physical elements along each of at least one route, in order from the route's start (source) to the route's destination (end). Typically, route information includes a set of all possible paths/routes among the factory's modules. typically including equipment module/s in the factory, control module/s in the factory, and/or manual module/s, if any, in the factory.

Typically, the auto-sequencing module of FIG. 1 receives “route information” for each route in a factory, including identifiers of all modules or physical elements e.g., containers along each route, in order e.g., from start to end of flow along that route. The route information may be defined manually or automatically.

Typically, the auto-sequencing module performs all or any subset of the following, suitably ordered e.g., as follows:
Generates List of Control Modules
Groups Control Modules into activation groups (or sequencing groups)
Provides e.g., receives from end-user, delay intervals governing transition from one activation group (or sequencing group) to the next.

The auto-sequencing module may send operating sequences (e.g., open, close etc. of containers along route) or implementation protocols to be exported to the vendor's PLC. There may be a sequence or implementation protocol for each route; each may comprise a concatenation or snippets for each of the elements along the route.

The term “operation table” herein typically refers to a stored indication, e.g., a table, stored e.g., in memory accessible to the PLC, of a group to which each element along a given route belongs. There may be a stored indication of this type for each route in the factory or each of any subset of routes in the factory. The groups are sequential and may be numbered 1, 2, 3, . . . Groups of elements in a given operation table for a given route may be activated in ascending order to cause material to flow through the given route, and may be activated in descending order to stop material flow through the given route, thereby to establish sequencing for using and terminating use of the route. Assignment of each element to a given group follows industry best practices and/or as described herein. PLC code snippets for activating or deactivating a given element along the route (e.g., pump, valve etc.) is typically stored, and each such snippet is called, or retrieved, or run, at a suitable time, depending on the sequencing. There may be stored typically configurable parameters indicating the duration of time to elapse between activation of group n and n+1 and/or the duration of time to elapse between deactivation of group n+1 and deactivation of group n.

The PLC's operation table function” performs all or any subset of the following, suitably ordered e.g., as follows:
Receive command to start/stop Route
Check Control Module availability, typically for all control modules along the route (according to route information)
Relate Control Module into current process
Check that Control Module is in “auto” mode. If not, command control module to enter auto mode
Lock the Control Module into “auto” mode
Energize or De-energize the Control Modules according to activation groups (or sequencing groups) and status.
The PLC's control module function performs all or any subset of the following, suitably ordered e.g. as follows:
Perform locking as defined by operation table function
Report current status
Move to “auto” mode. According to certain embodiments, all control modules along the route that controller has been commanded, by the operation table, to start, are moved to auto-mode.
Perform Energize or De-Energize as defined by operation table function, typically for all control modules along the route that controller has been commanded, by the operation table, to start or stop.
The right half of the flow in this diagram may operate inside a PLC extension.
Typically, Route Auto-sequencing according to embodiments herein, e.g. as performed by the autosequencing block in FIG. 1, orchestrates or sequences a set of physical elements (e.g. valves, pumps, motors, conveyers) along a route in a specific order, to enable safe, standard and best-practices based manufacturing operation. In process manufacturing, such operation may be either material transfer (typically between units) in-unit operation, or a CIP operation.

Once a route is determined (whether automatically or manually), auto-sequencing typically speeds recovery/optimizes production without code download, by performing all or any subset of the following control & automation tasks:
Allocating the elements to the current route action
Ensuring that the elements are not allocated to different action/route.
Ensuring that the elements are in Automatic (remote control) mode.
Ensuring that the elements are not reporting any alarms.
Determining an order in which elements may be activated to implement industry best practices) to allow the operation, while taking into consideration the amount of time to allow a sequence to complete before moving over to the next sequence.
Determining the order by which the elements may be activated to implement industry best practices) to stop the operation, while taking into consideration the amount of time to allow a sequence to complete before moving over to the next sequence.
Issuing (typically all) commands which may be necessary to activate and de-activate each element within the sequence, while taking care of any alarm being flagged.
Automatically reflecting, to the operator, the status of each route, and operational parameters real time present values involved in such operation.
Allowing authorized users—factory personnel or system integrator's—to make modifications to specific routing and sequencing parameters to optimize or recover production issues. For example, tune a sequencing timer to allow extra time for a valve open sequence to complete before starting a pump.

According to certain embodiments, the equipment is divided, or partitioned, or clustered into groups. If there are n engines, these may be clustered into n respective groups, each including a single engine, or may be clustered into less than n groups, where some groups include more than one engine. For example, there may be a single group of n engines. The groups of engines are numbered 1, 2, 3 etc. where the first group is the one closest to the source of the route, and the last group is the one closest to the destination of the route.

According to certain embodiments, valves are also clustered into groups. One group of valves is that which precedes (lies upstream of) the first group of engines, another group of valves is that which is downstream of the first group of engines but precedes (lies upstream of) the second group of engines, the third group of valves is that which is downstream of the second group of engines, but precedes (lies upstream of) the third group of engines, and so forth. The terms “precede”, “upstream”, and “downstream” depend on the route. For example, if a route goes from a to b to c, then a precedes b and is upstream of b, and c is downstream of b.

Regarding order of activation, according to certain embodiments, the first operation may be to close all valves, all along the route, which enable material to flow in any direction other than the route defined. For example, if the route defined is from tank a to tank b to tank c, any valves (e.g., junctions) which enable material to flow from tank a to any tank other than tank b, may be closed. Typically, then, valves which are junctions in that they enable flow in plural directions, only one of which (that which lies along the route) is desirable, may be grouped together.

According to certain embodiments, the subsequent operations, including opening all valves, enable material to flow from the source tank to the first group of engines, before the first group of engines is activated. Similarly, all valves which enable material to flow from the first group of engines to the second group of engines, are opened before the second group of engines is activated, and similarly for all other groups of engines.

According to certain embodiments, all equipment in a given group may be activated together. There may be an order of activation between groups which determines which groups are activated earlier, and which later, for a given process running on a given route.

Auto-sequencing typically comprises defining an order for open and close commands to the control modules in a path from start to end point (e.g., as defined below). The term “path” when used herein may be interchanged with “route”; a route's start may be termed the source, whereas the route's endpoint may be termed the route's destination. Typically, the route's source and destination are both receptacles which may store materials, e.g., tanks or fillers.

Typically, the output of auto-sequencing includes code for PLC for open and closed scenarios of a specific flow.

By setting active groups and their order (or by defining groups and their order of energizing or activating), e.g., as described below, a sequence ensures the correct order of flow direction, and ensures that other directions on the pipe sections are closed by their respective control modules.

By setting suspension time on valves and motors activation and closing, the ordered sequence ensures safe and durable control modules and pipe utilization.

A default suspension time of two seconds (say) is set between the active groups. Then the user may adjust the time as required by the control modules and the process.

It is appreciated that any parameter mentioned herein may have a default value in the system. However, specific default values mentioned herein are merely by way of example, and are not intended to be limiting.

The auto-sequencing may result in all or any subset of:
1. An ordered list of control modules and/or pipes
2. Each control module is related to one of the three (say) activation groups or sequencing groups
3. Activation group (or sequencing group) suspension time

The resulting output may be utilized by the user in system modules to initiate or stop the whole sequence for a group of the defined control modules.

Thus, auto sequencing includes generating order and/or nature of operations including for control module/s, sensors such as pressure sensors, etc. e.g., open valve for 1 min (say), then start motor for x time, etc., defining start procedure and end procedure for each pipe operation, defining as part of a sequence of all connected controlled modules that ensure the flow of material in the designated path, and defining the sequence for all related operations of a given pipe e.g., open close etc.

It is appreciated that parameters e.g., durations of 2 seconds, 1 minute etc. throughout this document are stipulated merely by way of example.

### Example Sequencing Logic:

A path (or route) may be defined as all the control modules on a pipeline, starting from a selected start point and ending at the selected end point.

All connected control modules on the pipe and its segments are included in the path.

The logic defines three activity states: Active_1, Active_2, Active_3.

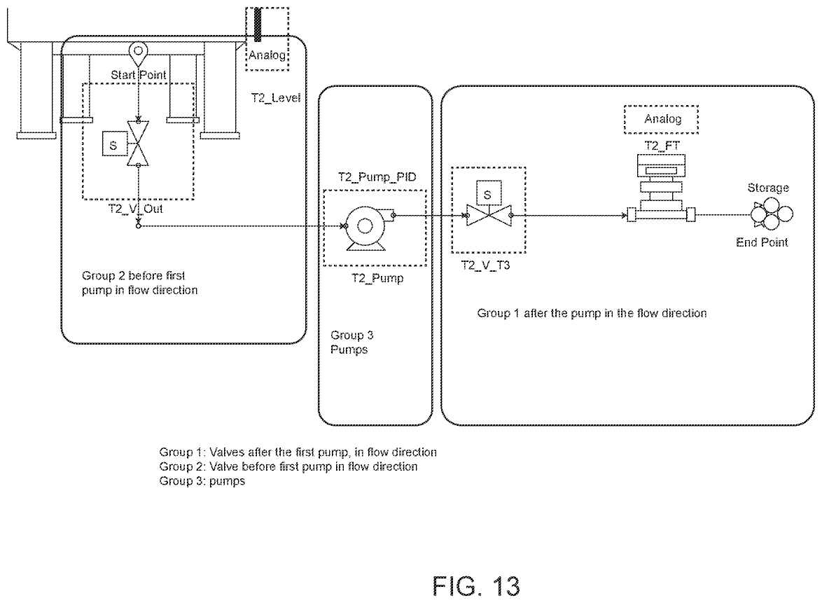

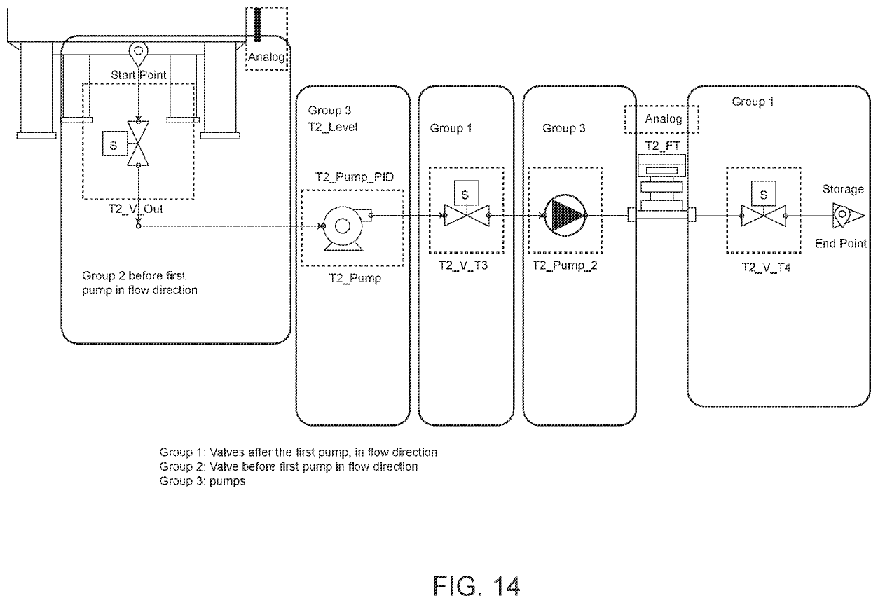

For example, as defined in FIGS. 13 and 14: First, identify state Active_1 =Group1 =all the valve control modules, after the first pump control module. If no pump is in the path, use the first valve as the “first pump”. The term “pump” herein is intended to include any instrument which generates material flow e.g., flow of a liquid, powder, gas, etc.

Then, identify state Active_2 =Group2 =all the other valve control modules in the path. Then, identify state Active_3 =Group3 =all the pumps and motor control modules.

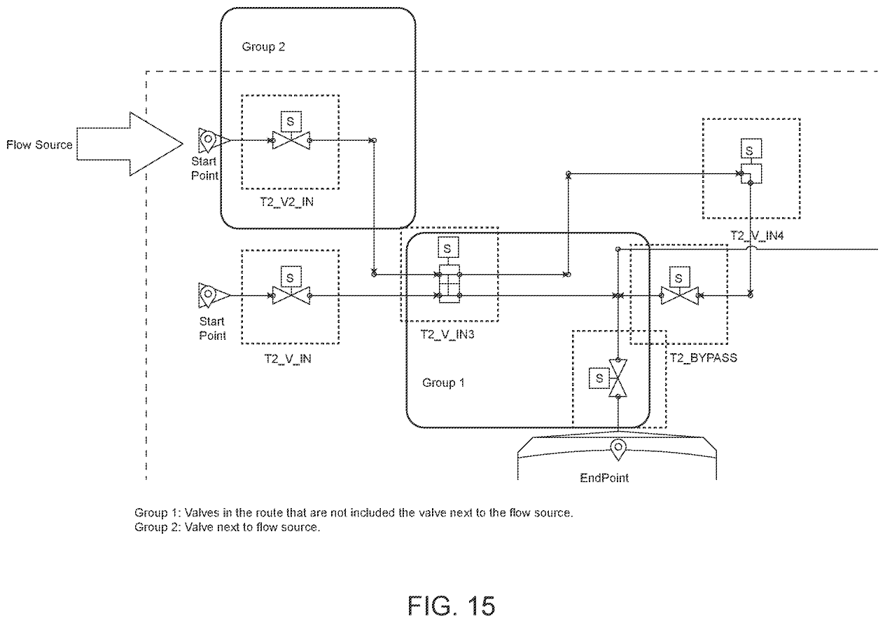

In FIG. 15, group 1 has the valves in the route that did not include the valve next to the flow source, whereas group 2 has the valve next to the flow source.

A trigger to increase or decrease a sequence may be a time parameter and/or an external interlock. An interlock may be a sensor or an action, or a combination between sensor and actions in any logical definition. Example: the sequence may increase (or decrease) if a specific sensor's actual value is equal or bigger than a specific setpoint, and a specific switch is in a requested status, or another specific sensor is in a requested status.

In auto sequencing, a “chain of conveyors” may be defined. Computation of the sequence of a “chain of conveyors” is equal to the number of members in the chain. The material flow is defined using the conveyors' direction. In activation of a chain of conveyors that has N members, and N is the last member in the chain, the activation may be as follows: N is the first member and a parameter “X” that counts the quantity of conveyors that are already in status “activated” may increase by one (X=1). After the trigger to increase the sequence is positive, motor number N−X may be activated, and increase the parameter X by 1. When N−X=1=⇒the last member in the chain is activated and chain of conveyors is in “started” status.

Deactivation is in the opposite direction, first motor conveyor 1 until motor conveyor N.

If one of the members is declared in “fault mode”, all the members allocated in lower position may stop immediately, and the member located in an upper position may remain operated.

### Example:

(Conveyor-1) (Conveyor-2) (Conveyor-3) (Conveyor-4) N=4.

If conveyor 2 is declared in “fault mode”, conveyor 1 may stop immediately, and conveyors 3 and 4 may remain active.

Paths may or may not have sensor/s to monitor flow, depending e.g., on use case and/or on the actual equipment used.

Delays may be needed between the activations.

Parameters (e.g., durations, pressure, weight, etc.) may be static or dynamic parameters; these may be received from sensors or by manual means.

Auto-sequencing may or may not be preceded by deriving (e.g., from a P&ID (piping and instrumentation diagram) drawing, in either raster or vector format), a manufacturing factory model that includes all equipment, controlled equipment, sensors, pipes, etc. and their connections. It is appreciated that pdf diagrams may alternatively be used anywhere herein.

In diagrams, typically, intersecting lines do not mean intersecting pipes. Lines connected or almost-connected to a module symbol typically denote a port at the point of connection. In some diagrams, each symbol, which may include plural shapes such as 2 triangles and a rectangle, is defined as a separate entity. In other diagrams, no such entities are defined.

Auto-discovery may take place, based e.g., on a drawing which may be stored in a working area, assigned to an individual end-user, within the system of the present invention, that was either manually drawn using controls from a predefined library, or imported from a drawing file P&ID to the working area, aka system working canvas. According to certain embodiments, blocks are classified into control and equipment modules, optionally manually by user input. The system may show a user certain blocks, and the user then defines their classification, by selecting from a system library of predefined equipment and control modules.

The system may be configured to analyze the drawing starting on the recipient connections (tank, reactor, filters, membranes, etc.) to control module to piping and conveyors.

As shown in FIG. 28, the method of the present invention may include all or any subset of the following operations, suitably ordered e.g., as follows:
i. Definition/discover of unit recipients (tanks, reactors, transportation and service lines . . . )
ii. Auto attachment of control modules to units
iii. Autodiscover of routes
iv. Autodiscover of material flow
v. Autodiscover phases and phases definition based on editable templates.

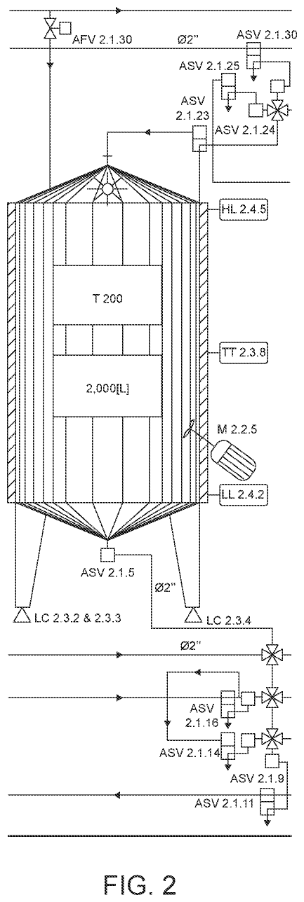

Units may be automatically identified. The system may analyze the drawing using shape recognition, picture recognition, text recognition key word in the graphic file and operator inputs starting for the recipient (tank, reactor, filters, membranes, etc.,) from the containers with all the connections to control module or/and piping, and conveyors, as shown in FIG. 2, for example.

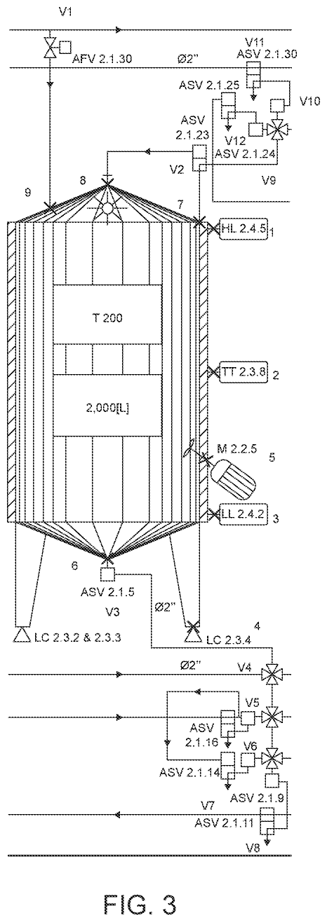

Unit Auto discover may be based on a tank (which is used here and elsewhere, for simplicity, as an example of a unit recipient, and could alternatively be replaced, mutatis mutandis, with other equipment such as, say, a reactor). In FIG. 2 there is a block defined as a tank with several connections to control modules and pipes, and to the pipes connecting valve control modules. Also, sensors are connected to the tank, as shown in FIG. 3. The tool recognizes automatically the graphics blocks defined as tanks and also for the graphic block name that is called “Tank”. For unrecognized shapes, the user may define the graphic block as a tank in a specific user interface that presents the pictures/shapes that were not auto recognized. According to certain embodiments, unrecognized symbols may be ignored and/or may be treated like a picture and/or may be shown to a user, manually categorized as a given module, and then the “picture” may be replaced by data in system databases defining that given module.

FIG. 3, for example, includes:
at reference numeral 1: Connection to Digital High-Level Sensor.
at reference numeral 2: Connection to Analog Input Temperature.
at reference numeral 3: Connection to Digital Low-Level Sensor.
at reference numeral 4: Connection to Analog loadcell weight Sensor
at reference numeral 5: Connection to agitator motor.
at reference numeral 6: Connection to pipe to discharge valve.
at reference numeral 7: Connection to pipe to material circulation.
at reference numeral 8: Connection to tank CIP (cleaning in place).
at reference numeral 9: Connection to tank water filling.

Recognition of connections to the tank is based on the recognition of different graphic blocks that are connected to the tank block, as described in FIG. 3.

Attachment of control modules may occur.

After finding the pipes/conveyors (as shown in FIG. 3, elements 6-9), the attachment of control modules of type of valves/pumps/dividers is based on the following definition:

The control module is directly connected to the unit, and does not divide the flow to multiple directions. If division of the flow is to the same unit, it is defined as not dividing the flow).

### Example/s:

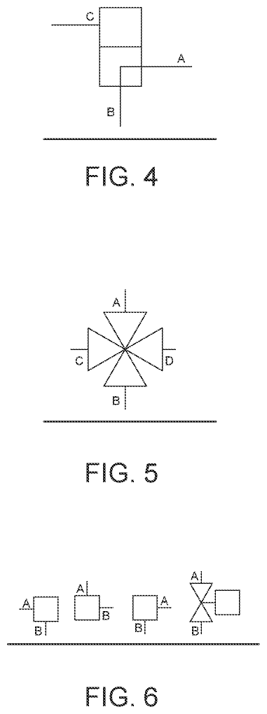

FIG. 3, V2: is a valve on/off 3 ways with 3 connectors A, B, C. A is a connector indicated as an input, and B and C are output connectors. In the example, B and Care connected to the tank/i unit; this layout does not present a diversion, and valve V2 is attached to the unit, e.g., as shown in FIG. 4.

FIG. 2, V9 is a Mix Proof valve. This type of valve has 4 connectors, A, B, C, and D, e.g., as shown in FIG. 5.

It is appreciated that in the description herein, there may be plural instances of a single type e.g., several valves of a single type.

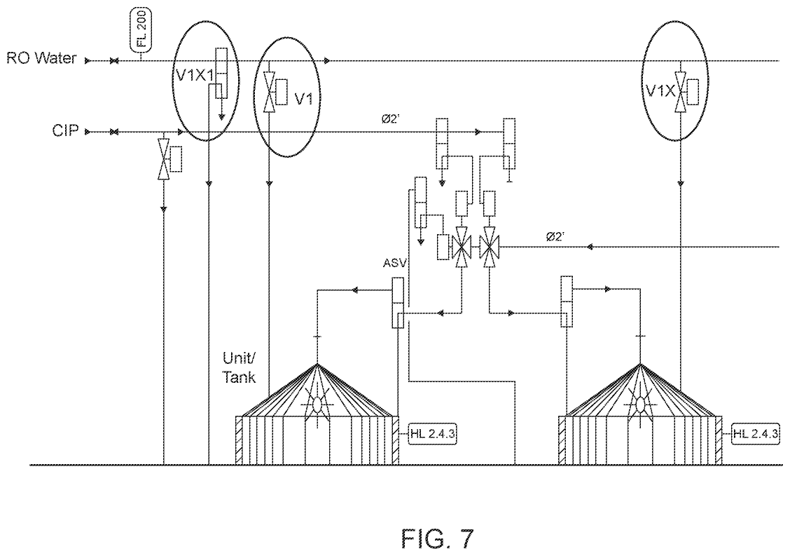

From A to B and from C to D there is always flow, in this example. If the valve is activated, the flow may be to all connectors. This valve is used to permit diverting the flow to all directions by activating the valve, and to allow the flow between the fix points without the danger of mixing between the flows. The valve is typically attached to the unit that can receive/send from the unit. Valve V9 is attached to the unit. Stop valves e.g., as shown in FIG. 6, are valves with 2 connection points A and B. The flow is always between both connections, and may be with flow, with activation of the valve (N.C. normally closed), or flow when the valve is not activated (N.O. normally open). FIG. 2, V1 stop valve, is shown in FIG. 7. Valve V1 is a stop valve type butterfly. Like other stop valves, it has two connections, one connected to the “Unit” and the second to a line that supplies RO water to several tanks/units. One connection is clearly connected to the “unit” and the second connector is to a common line (as valve V1X and V1X1) valve. V1 is part of the “Unit”.

Equipment & unit upgrades may be provided e.g., by upgrading the way the system handles equipment and its aggregation into a unit, in order to conform to ISA-88 compliance, provide a better infrastructure to define batch-related activities (phases), and innovate, by allowing the system-Q-Engine to auto discover the relevant equipment modules and control modules associated with a Unit; and/or by automatically identifying and developing OT (operating table) and phases that may be necessary and that are possible for any unit and/or to make the system (even more) SCADA-ready by automatically generating tags that support naming conventions expected by SCADA systems (per ISA-95).

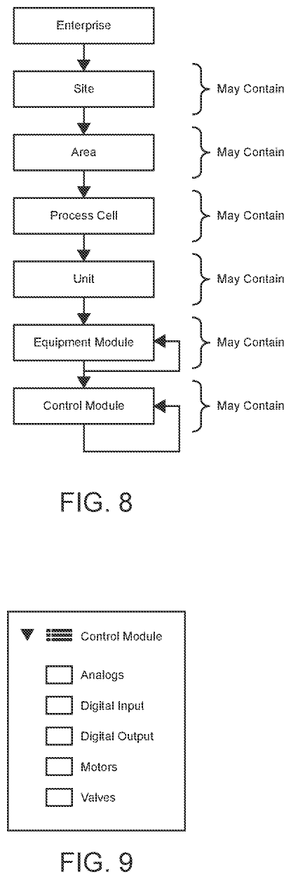

FIG. 8, for example, represents a possible standard e.g., ISA-88; as indicated, according to certain embodiments, some objects may be compulsory (e.g., unit), and others may be defined as optional.

Upgrading may include renaming the current “Equipment” object to become “Control Module”, adding a new “Equipment Module” object which is a set of Control Modules, (represented by a folder in the navigation tree), and adding a new “Unit” object which is a set of “Equipment Modules”.

The upper ISA-88 levels-Enterprise, Site, Area, Process Cell (which are physical notations, may all be implemented by the user-if needed-as hierarchy of the current “Area” object.

For example, a Mixing Unit (i.e., where the key operation is mixing materials) is comprised of a Mixer Equipment Module, a Motor Pump, three inlet valves, and two outlets.

### General Guidelines for Logic May Include All or Any Subset of the Following:

1. Specific Equipment module may only be assigned to one Unit.
1. Specific Control Module may be in more than a single Unit (shared). For example, a controlled valve that directs the material flow to two units.
1. An Equipment Module could be attached to an area level (i.e., not be part of a specific unit).
1. The unit may need to have at least one equipment module (a unit may have only one equipment module in a unit).

### General Guidelines for UX May Include All or Any Subset of the Following:

1. Adding new Unit/Equipment Module/Control Module by three input methods (that all result in the same info in the system):
A. Via navigation tree (e.g., right click, Add Control Module)-traditional popup for attributes input
A. Via P&ID Import and then highlight items with missing info so that by clicking, the relevant popup opens to complete and approve.
A. Via DYI Graphics (currently HMI edit page)-when adding an element-popup to get input which be may necessary as in tree input.

Typically, a control module is a digital or analog element that is either controlled or monitored (i.e., provides input). If human input (quantity, confirmation, etc.) is provided, it may be implemented through a control module. The system may change current “Equipment” object to “Control Module” (keeping the same underlying elements of valves, motors, . . . ), same logic and attributes e.g., as shown in FIG. 9.

“Equipment Module” may be added as a new database object and a new level under “Unit” (e.g., as described below) and on top of “Control Module”. When adding an Equipment Module, all or any subset of the following attributes may be provided:

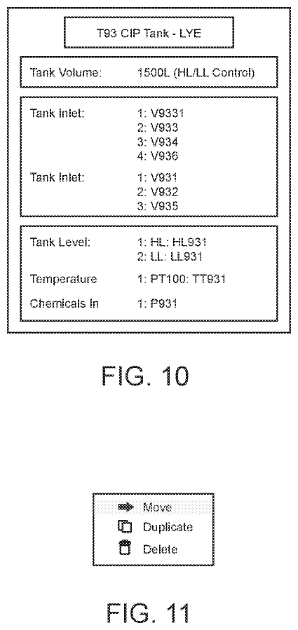

Equipment Module has a “Type” attribute. The Type defines a list of attributes that are required as user input. For example, e.g., as shown in FIG. 10, a tank requires definition of inlets and outlets, level indicators, etc.:

Per each Equipment Module type, the following user input may be required e.g., as seen in 501—Equipment Unit Fields Definitions table herein.

Logic: A specific control module may appear in more than one unit.

Adding new equipment module-manually, via navigation tree: Note: future stages may include graphic DYI buildout as well as automatic operation, via a P&ID. Enable “Add” action only via “Area” right click: “+Equipment Module” action. Area may have zero—n equipment (may have duplicate of same types—there is no limitation). Open popup window to capture the key fields:

Graphical representation of the equipment may be elected at the HMI stage.

On a defined “Equipment Module” allow right click action: “Connect Control Modules” which opens a list of all Control Modules (e.g., using Figma). Notations may include all or any subset of:
Control Modules already connected to the EM.
Control Modules already connected to other EM.
CMs (control modules) that are not yet connected.

Filters on the list may include all or any subset of:
Group1: CM type (e.g., analog, digital, other)
Group2: connected to this CM, to other CM, not connected

By function: valve, motor, analog, [or go to further level of “Temperature Control”, Weight”, etc.

Actions on each CM may include: connect to CM (if not already connected) or disconnect from CM (if connected).

Verifications: List of pre-defined checks that may be run and may raise errors or alerts re the CMs included in the EM.

The system may enable “Edit” action on Equipment module-open the definition popup with the current settings and attached Control Modules.

The system may enable “Duplicate” action on Equipment module (important for as long as templates are not available).

The system may enable “Delete” action on the equipment module.

Navigation actions may be provided e.g., a control module may be moved from one equipment to the other. When duplicating, it creates an additional similar control module in the same equipment, however asking for a different ID by presenting the Control Module Popup with an empty ID# field e.g., as shown in FIG. 11.

Unit is a known term in batch operations (e.g., as in ISA-88), and may comprise one or more Equipment Modules that together perform a controlled operation, such as mixing raw materials. Typically, a unit is of a certain type, e.g., Raw Materials, Reactor, Oil Service (selected from a pre-defined list that may be extended). Based on the type, the system may auto discover which operations are likely to exist, e.g., “Empty” /“Fill” a Raw Materials Unit. These form the columns of the OT that is associated with the unit, including the column names.

The control modules that are associated with the Equipment Modules of a particular unit are the ones forming the rows of an OT for the unit. Based on the route of Material Flow (e.g. from a starting point to an endpoint) the system may determine the content of the OT (including auto sequencing). Equipment Module is unique to a single unit; however, the control module may be assigned/shared across more than a single unit or equipment.

According to certain embodiments, a unit is always associated with an area (for physical attribution). If a unit is not of a type already known to the system (“Other . . . ”), it is given a name by the user, and upon request (“Save as template” checkbox) may be later used. In case of a “Other”—the system may create an OT containing just the rows, for the user to add columns and fill in the content. In case “Save to template” is selected, the columns' names may be saved as part of the template; the content may, if desired, be used as well.

Any suitable sequence of defining a unit vs. OT may be used.

Unit Attributes may be provided. Unit Type/s may be provided. Specifically, a unit may have a defined function: e.g. all or any subset of the following:
Raw Materials
Reactor/Mixer
Buffer
Service (e.g. all or any subset of Oil, Fuel, Cooling, Heating)
Filler
Other from Template
Other—in this case enter a name and ask which parameters may be deemed necessary. It may be then saved as a template.

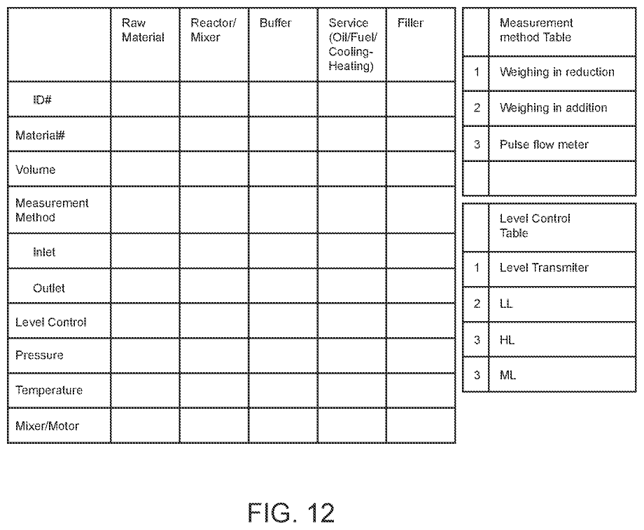

Per the unit type, the system typically queries for various fields; e.g. as in the table of FIG. 12 (e.g., in 501—Equipment Unit Fields Definitions). If there is only one equipment module in the unit, then the default values may be taken from that equipment.

Navigation may include defining a unit. Until a unit has at least one equipment element, it may be grayed out (e.g., to indicate that it needs to have at least one equipment element). In a manual method, the method may build equipment and add to the unit. The unit may have multiple occurrences of the same equipment type (e.g., two mixers that may be used with two different materials). The method may drag & drop an equipment (module) on a tree to a unit, or an area is an implied ‘Move’ operation. Unit characteristics may be provided; when selecting a unit, all or any subset of the following unit attributes may be displayed:

Unit Type Templates for OT (operation table): If a unit is not of a type already known to the system (“Other . . . ”), it is given a name by the user, and upon request (“Save as template” checkbox) may be later used. In case of an “Other”—The system may create an OT containing just the rows, for the user to add columns and fill in the content. In case “Save to template” is selected, the columns names may be saved as part of the template. The content may be used as well.

LIBRARY: may contain classes that are shared between a project or projects.

Library Classes: Phase.

AREA: Area may be for continuous processing, or batch processing, or both.

The area icon may have three flavors to reflect the above respectively. If an area is continuous, then may not be allowed to add phases and recipes to units.

Pan View: Area, Library, Process view. Pans may have open or close view, and one of the above views may be selected.

Unit Operation Table: Typically, the operational control module that was attached to a unique unit automatically belongs to a group of control modules named “Operation Table”. This operation table is typically responsible for managing the group for statuses, commands, actions, and reactions.

Route: The operation table is typically responsible for operating the controls modules that are grouped as a “Route”; each route herein may refer to a particular flow of a particular material (e.g. a product ingredient or a cleaning material for cleaning containers/tanks/pipes) through a factory's containers and/or tanks and/or pipes. The term “container” herein is intended to include any receptacle for liquids or powders, or any other materials.

A Cross-units (multiple operational table) route may be provided. For example, a Master-Slave Route may be provided. When a route is defined, the route may use one or more “operation tables”. Each operation table that is part of the route may have a state with a unique identification name. This name is the same name as the route. When an operation sequence is defined, for each operation table state the quantity of groups in the activation and deactivation is also defined. One of the operation table states that contain the higher group may be defined as “master”, and all the others as “slaves”. The master may manage the activation and deactivation of the route.

A route may be a cross-operation table, and the routes are defined between “Start flow” to “End flow”.

“Start flow” is the point of start of a given flow, and may be the bottom of a tank or valve connected to a flow source as a tap water valve that is part of a city's water supply. End flow is the point that the flow ends, and the flow pressure becomes 0 as in the inlet of a tank, flowing out of a pipe to a bottle or drainage.

Automatic identification of start/end flow point and flow direction may be provided. Any control module in which one of the ports is not connected to other port of another control, is considered as a start/end flow.

Routes in a factory may be identified, and/or route information or other data described herein regarding a factory, may be provided, e.g. based on any embodiment herein or on published U.S. Ser. No. 17/283,676 to Javier Bruno Farkas entitled “System and method for computerized programing of a controller of an industrial system” published by the United States Patent and Trademark Office on Dec. 9, 2021 under publication no. US 2021/0382450, the disclosure of which is hereby incorporated by reference. The system may use the same technology and the “start flow” and “end flow”, and may automatically find all relevant routes.

Recognition and management of “Non-controlled modules” (filters, non-return valve, relief valve, manual valve) is now described, according to certain embodiments. During the import or manual drawing of the P&ID in the “working canvas”, the system may recognize or the user may define “non-controlled modules”. Such “non-controlled modules” may be used in Adaptive Control-Al and/or an Auto-alerting system.

Smart functionality may include all or any subsets of the following:
i. Hardware auto-configured by areas.
Based on areas and units, and the type of hardware of the project, the system may create I/O list based on control modules.
ii. I/O test from “working canvas” and documentation.
iii. identification of soft sensors.
iv. identification of parameters and alarms.
v. identification of Route Operational Sequencing.
The “route” that was discovered may be a group of control modules, each one of which typically must be in a defined position to allow the flow from a “start flow” to “end flow”.
This route typically must be activated and deactivated in a specific sequence, depending on the “flow cause”, e.g., to ensure controlling functionality.
Route sequences are time delays between the group e.g., to ensure that the previous group is activated as requested before the next step.
The sequence may be attached to a sensor as an interlock e.g., as in FIGS. 13-16.
When only one control module is part of the route, the control module may be part of group 1.
vi. identification of Material Flow data (e.g., material flow model as in ISA88) may be provided. Based on the data from the “Working canvas”, “Units definition” and “Routes”, the system may build a database of the material flow and interconnection between units. This may include suitable units and line status and linkage based “material flow” and/or a special unit-CIP cleaning in place.

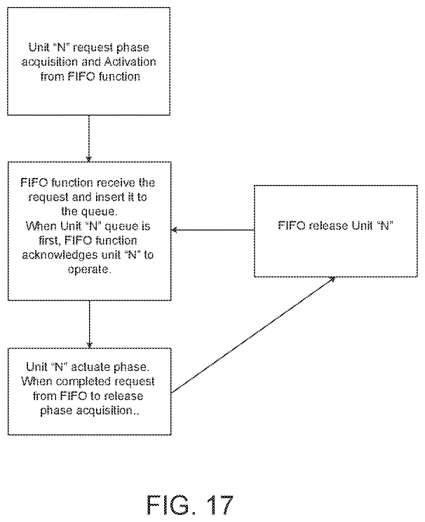

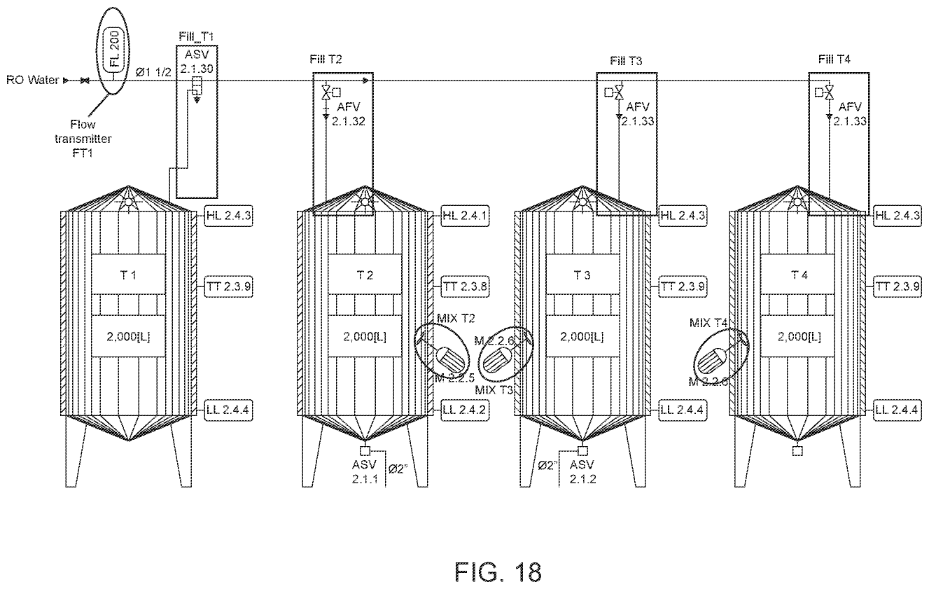

Re in-place cleaning, The system may detect CIP unit based on auto-detection and/or user definition thereof. For the former, there may be several options e.g., all or any subset of the following options for Auto detection of a CIP center:
a. If there is a line that is connected at least to a supply tank and the line may supply the liquids to a specific unit, and from this specific unit may return to the supply tank.
b. One of the supply tanks is connected to a chemical dosing system.
c. One of the supply tanks may be heated.
d. The supply line may be heated.
e. There is flow control in the supply line.
f. There is conductivity control in the return line.
vii. identification of phases e.g., actions that may be performed in a unit.
Phase is an action that a unit may perform based on the control equipment involved, parameters, and user's inputs.
Phase may be defined as “Share phase” or Non-share phase”, depending on the measurement equipment included in the phase, as defined in the “unit definition-measurement option”.
If the measurement module serves more than one unit, and if the serving to more than one unit may affect the measurement, the phase may be used only one by one unit, and a “FIFO” function may be used to sequence the filling.
Share phase flow chart is shown in FIG. 17.
   A shared and non-shared phase example is shown in FIG. 18.
   As shown, there may be a P&ID that describe a group of tanks that may be filled with reverse osmose water (RO water) and the tank may be mixed (T2, T3 and T4).
      Shared phase-RO Water.
         Fill_T1, Fill_T2, Fill_T3 and Fill_T4 are phases with a common measurement control module, flow transmitter FT1.
         Only one tank at a time may be filled and measured.
         Thus, the phase is defined as “shared”.
      Non-Shared phase-mixing may be provided.
viii. Auto documentation.
ix. Auto IQ OQ and PQ for pharma.

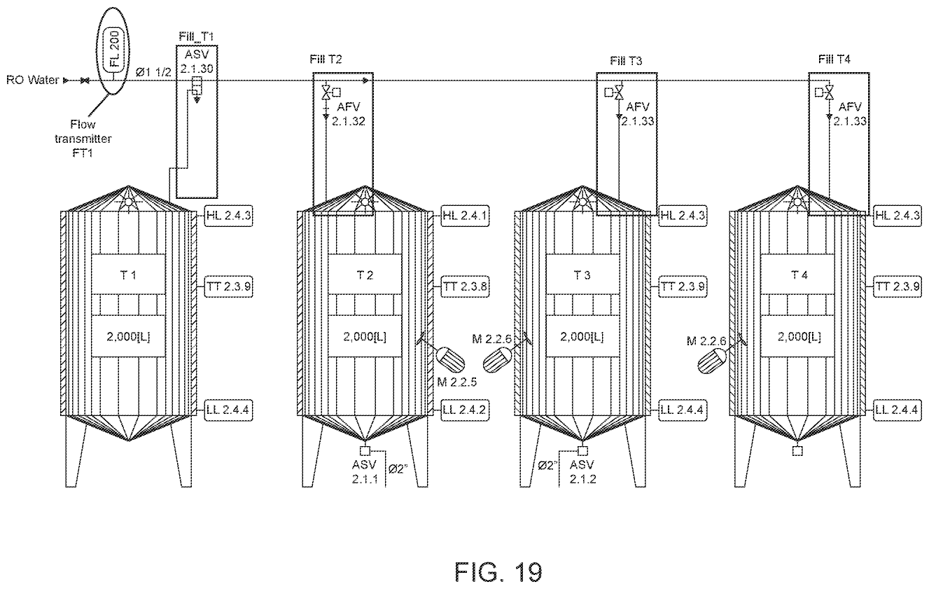

Adaptive control AI may include all or any subset of the following:
i. Route sequence delay adjustment.
Route sequence may be built linked to a sensor to avoid hydraulic shocks.
In case that the route is not built with sensor feedback, the system may compute the real time sequence using all or any subset of the following inputs:
Flow sensor in the route; and/or
Pressure sensor in the route; and/or
Pump speed feedback; and/or
Operator input.
ii. Route malfunction detection based on operations history of phases and or routes operations and supply and services (steam, cooling liquid, cooling chiller, raw material temperature, pressure in supply line, parallel similar phases) analyzing.
iii. Predictive maintenance for control modules
Based on the control modules database, the system may read real time data from each one and create an operational profile for each control module and statistic compared between the profiles.
Example: if there are several similar valves, may use the same control module catalog number.
The system may compare between the operational profile and send an alert when it finds a deviation from standard.
For each valve the opening time is X+−5%. If one of the same catalog number deviates from this common profile, the system may send an alert.
iv. Leak detection.
The system defines and manages the routes.
In the example, RO water may be filled to T1 (route Fill_T1), T2 (route Fill_T2), T3 (route Fill_T3) and T4 (route Fill_T4) having a common flow transmitter FT1.
The system has the information that there is no manual valve in the respective line.
If transmitter FT1 senses flow while no route is activated, the system may send an leak or spillage alert, e.g., as shown in FIG. 19.

Many variations of the system shown and described herein are possible. For example, any suitable method may be employed to auto-generate control sequencing (typically comprising PLC code) of how to start a certain flow sequence or route, or how to stop a given route. For example, to automatically generate PLC code to operate each tank/container or other physical element along the route, the system may, first, store, for each known type of tank/container/physical element, a first snippet of PLC code or implementation protocol which starts that element, and a second snippet of PLC code or implementation protocol which stops that element. Typically, only one first snippet and one second snippet need be stored, if a given known type of tank (say) is installed in plural factories, all of which are end-users of the system. It is appreciated that first and second snippets which respectively activate and de-activate an element may be in reverse order e.g., the first action performed by the first snippet may be the last action performed by the second snippet.

Then, once a given end-user wishes to operate a given route through her or his factory, and once the route information defining that route is available, the system generates:
a. PLC code for starting the route, which includes the first snippets of all physical elements along the route, arranged in the order the elements appear in the route from start to finish; and/or
b. PLC code for stopping the route, which concatenates the second snippets of all physical elements along the route, arranged in the order the elements appear in the route from start to finish (or from finish to start).

The PLC so generated may be used as an operating sequence (e.g. as shown in FIG. 1) or implementation protocol e.g. for a given route. This may be, for example, in order to, say, cause material to begin flowing through the route, or to cause material flowing through the route to cease flowing.

According to certain variations, a method for controlling an industrial process in a factory is provided, where the industrial process may, for example, involve a flow of material. The method may include accepting a definition of a route extending from a source to a destination, along which the material flows, and/or dividing all engines aka motors along the route into at least one group of engines including a first group of engines which is closest to the source; and/or automatically generating source code (aka PLC code) for Programmable Logic Controllers controlling valves along the route. The PLC code may be configured to:
a. close valves along the route which enable material to flow in any direction other than along the route (“junction valves”); and/or
b. open valves downstream of the first group of engines and, subsequently, to activate the first group of engines.

According to certain variations, the engines may be divided into at least two groups of engines, including a first group of engines which is closest to the source, and at least one second group of engines downstream of the first group of engines. The PLC code may be configured to open valves downstream of the second group of engines and, subsequently, to activate the second group of engines. The PLC code is configured to open all valves downstream of the first group of engines and upstream of the second group of engines and, subsequently, to activate the first group of engines.

According to certain variations, the PLC code may include at least one dynamic start criterion, determining when to start at least one control module along the route, comprising a condition defined on at least one sensor output received in real time from at least one sensor along the route. The PLC code may include at least one dynamic stop criterion, determining when to stop to at least one control module along the route, comprising a condition defined on at least one sensor output received in real time from at least one sensor along the route. The sensor output may, for example, include a pressure reading read from at least one tank along the route.

According to certain variations, automatically generating comprises auto attachment of at least one control module to at least one unit.

The system code to convert information in any repository described herein into PLC code (say: using “structured text” format, or any other PLC code format) may be configured to perform all or any subset of the following operations a-d, suitably ordered e.g., as shown:
a. Provide DB with info. Input may include a diagram of a factory with all containers and pipes, and/or a process which an end-user has defined, for making a product in the factory.
b. Provide a library of predefined templates of the structured-text, each template including variable names such as “method name”. For example, one template in the library may be for performing a method invocation.
c. Template/s may be selected from library
d. In each selected template, the code automatically replaces respective variable names. For example, in a template on how to do a method invocation, replace “method name”.

According to certain embodiments, if “structured text” format plc code is being used, each data asset may have, stored in the system, a translation on how that data asset looks in structured-text format.

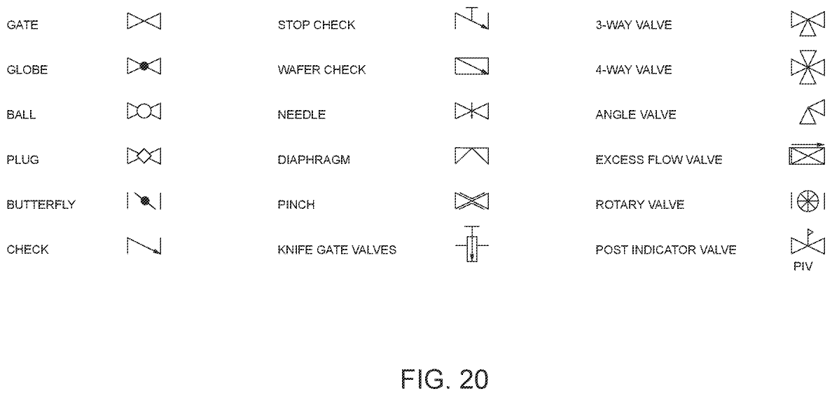

The system may define and manage a DB of P&ID shapes, symbols, and images for comparison, and ML models for image recognition patterns. To recognize these shapes, any suitable typically ML-based pattern recognition algorithms may be employed, such as but not limited to Statistical Techniques, Structural Techniques, Template Matching, Neural Networks, Fuzzy logic or Hybrid Models, or any combination thereof. This DB may comprise different representation of the common P&ID symbols, and their different sizes and drawing variations. Example symbols which may appear in this DB are shown in FIG. 20.

For each symbol different sizes and/or line weights, and/or rotation angles may be defined.

It is appreciated that the information created by the P&ID analysis process described herein may alternatively be generated manually. There may be a requirement that certain items of information may be included. All or any subsets of the following items of information (items info1-info8) may be required:
info1—Vector model, which may include all graphical shapes, including lines, dots, polylines, circles, arcs, ellipses, and other; and/or block and shape groups representing P&ID symbols, tanks, and graphical annotations, and/or lines, arcs, freehand lines, representing pipes and flows.
Info2—Symbols classification. P&ID shapes, blocks, and symbols may have a classified classification, and may be related to P&ID symbols and the system DB.

Tanks shapes, blocks, and symbols may be classified and related to P&ID symbols and the system DB. Pipelines may be classified.

Info3—Modules. Module types (or modules) may be classified into classes such as, say, all or any subset of: Equipment module, Control module, Manual Module, or Annotation shape.

A list of modules may be created in the system DB with all or any subset of the following attributes:
functionality: valve, motor, pump, mixer, heater, pressure sensor, etc.
type: for example for valves, is it valve on-off or valve PID, etc.
flow direction: single directional, bi-directional
connection ports and their flow direction: input ports, output ports
titles and annotation texts.
Modules' reference to parent module attachment may be defined, for example, all attached control modules for each tank equipment module.

It is appreciated that some control modules may be “directional” e.g. as described here: https://store.boschrexroth.com/Hydraulics/Valves/Directional-valves/Directional-control-modules?cclcl=en_RO.

info 4 Pipelines. Certain information may be required to be extracted for each pipe line e.g., all or any subset of the following:
Line segments
Joints
Bridges
Flow direction per segment
Classification as external inflow/outflow or internal line
Connectivity to module ports.

Info5—Processing Units. A group of control and equipment modules, including its piping configuration. Processing Unit classification: Tank based Unit, Non-Tank based Unit, CIP Unit.

Info 6—Flow routes: Configuration of groups of control and equipment modules and their piping which represent a flow of materials from one point into the others. Start and end ports of the flow route. Classification as internal or external and/or as incoming/outgoing.

Info7-Area—A group of processing units which are managed within the same logical area.

Logical area: is a unit of group of units that are managed as a group because of a similar operational option (example: mixing area, raw material area, assembly machines area) or by geographic installation.

Info8—Non-identified shapes e.g., a list or set of shapes, blocks, graphics, texts, which was were not recognized and not classified. By default, these may be classified as annotations.

According to certain embodiments, the input to auto-sequencing, in which PLC code is generated (typically for a user-designated make and model of PLC controller) to activate and/or deactivate route/s in a factory includes all or any subset of:
a. A set of valid routes interconnecting equipment or modules or units in a factory. Typically, each route includes an indication of the route's starting point and endpoint and/or a sequence of control modules which falls along the route, typically beginning from the control module closest to the starting point, and ending with the control module closest to the endpoint.
b. Indications of overlap between the routes
c. Indications of all junctions along each route and, for each path extending from the junction other than along the route itself, an indication of at least one control module able to block flow of material flowing along the route into that path, aka spillage. Typically, the control module which is indicated is the one closest to the junction, to minimize spillage.
d. Classification of the type of material which flows over each segment of the route e.g., grains vs. liquid vs. gas vs. powder and/or fuel vs. water vs. cleaning fluid etc.
e. Determining which valves (or pumps etc.), depending on each valve's sequence along the route relative to receptacles or other sources of material along the route, are “primary” valves (or pumps) which release or block material flow, as opposed to valves whose activation or deactivation does not release or block material flow.

Typically, the PLC code is generated in advance and stored in advance for plural routes in the factory, e.g., all routes deemed likely to be used, and is then retrieved from memory for a given route when a manager or an automated route selection functionality selects a certain route for activation or deactivation.

Upon selection of a given route from among the set of valid routes in the factory, the system typically executes verification to ensure that a route does not overlap with an already operating route, to enable prevention of simultaneous activation of overlapping routes.

Typically, a route once verified e.g., if verified, receives its logical allocation of control modules e.g., all control modules along the route are allocated to that route and typically cannot then be allocated to any other route.

Typically, each control module is then checked to ensure operability e.g., by conducting status checks.

Typically, each control module which is operable and verified, is then logically locked to prevent digital overriding of the allocation to this particular route.

At this point, the route may be activated by operating all elements along the route in a sequence determined by the groups to which the elements belong, as described elsewhere wherein. It is appreciated that activating the route may involve opening certain elements for material flow therethrough, and closing other elements for material flow therethrough.

For arbitration purposes, parameters in the operation table may again be taken into account. For example, if a single control module is allocated to two routes simultaneously, and its role in the two routes contradicts (e.g. a valve allocated to routes 1 and 2 needs to be simultaneously open for purposes of route 1, and closed for purposes of route 2), then arbitration is performed, e.g., to continue one of the routes, and to issue a warning that the second route is being defaulted in favor of another route.

It is appreciated that interlock is sometimes defined between plural elements along the route. The system herein typically supports re-defining interlock dynamically or in real time, and, responsively, the PLC controller takes into account the new interlock condition without code modification, hence without down-time for the route.

It is appreciated that auto-sequencing for a given route which includes categorization of each equipment or module along the route into one of several ordered activation groups, is typically achieved by applying business rules, formulated according to best practices known in the industry for sequencing operation of factory equipment, which facilitate this categorization. Some business rules may be specific to the type of material flowing along the route, and other business rules may be general for types of materials. For example:

A business rule which may be used for this purpose is material flow activation in an order beginning from the most downstream elements along the route, and ending with the most upstream elements.

Another business rule which may be used for this purpose is activation in an order beginning from the most downstream elements along the route. and ending with the most upstream elements. Another business rule which may be used for this purpose is de-activation in an order beginning from the most upstream elements along the route. and ending with the most downstream elements.

Another business rule may be that “primary” elements appear in a later activation group than non-primary elements which are upstream of the primary element. Typically, all primary elements appear in the last material flow activation group and in the first material flow de-activation group.

Any other business rules may be employed according to best practice as known in the industry for the order of activation and/or deactivation of elements along a material flow route which is being activated or deactivated.

An operation table is built for each route, typically using the business rules and typically indicating, for each element along the route, the group to which that element belongs. Typically, if activating material flow involves activating the groups from first to last, deactivating material flow along the same route involves deactivating the same groups from last to first.

The elements belonging in a single group may be activated simultaneously. Typically, all elements in each group are activated before even the first element in the next group is activated, and all elements in each group are de-activated before even the first element in the previous group is de-activated.

According to certain embodiments, the PLC code which activates a route comprises snippets of PLC code for activating each element in the first group, followed by snippets of PLC code for activating each element in the second group, and so forth.

According to certain embodiments, the PLC code which de-activates a route comprises snippets of PLC code for de-activating each element in the last group, followed by snippets of PLC code for activating each element in the next to last group, and so forth.

Typically, the PLC code includes (typically overridable or configurable) parameters determining intervals of time to elapse between activation of group n or the last element therein and activation of group (n+1) or the first element therein, and similarly for deactivation.

Thus, to generate PLC code for activation or deactivation of a given route, snippets of PLC code are retrieved and concatenated in a suitable order e.g., as described above and with suitable intervals between groups, e.g., as described above.

According to certain embodiments, the operator can partition a single group into plural smaller groups and/or can merge plural groups into a single larger group including all elements in each of the plural groups.

The snippets of code for all elements controlled by a given PLC controller are typically stored in that controller's memory. When groups are merged or partitioned, this typically involves changes in the group number that certain elements belong to (e.g., element x belonged to group 4 which was partitioned into 2 groups numbered 4.1 and 4.2 and element x now belongs, say, to group 4.2.). The controller then controls all elements along the route by activating and/running and/or retrieving and/or calling the relevant snippets of code in the relevant order as determined by the new number of groups to which the element now belongs. It is appreciated that the above embodiment is advantageous in reducing down-time for the factory because no code is modified when groups are partitioned or merged.

Similarly, the interval between groups is typically configurable, and again this results in the ability to adjust for a new interval between groups without code modification, hence without down-time for the route.

It is appreciated that terminology such as “mandatory”, “required”, “need” and “must” refer to implementation choices made within the context of a particular implementation or application described herewithin for clarity, and are not intended to be limiting, since, in an alternative implementation, the same elements might be defined as not mandatory and not required, or might even be eliminated altogether.

Components described herein as software may, alternatively, be implemented wholly or partly in hardware and/or firmware, if desired, using conventional techniques, and vice-versa. Each module or component or processor may be centralized in a single physical location or physical device, or distributed over several physical locations or physical devices.

Included in the scope of the present disclosure, inter alia, are electromagnetic signals in accordance with the description herein. These may carry computer-readable instructions for performing any or all of the operations of any of the methods shown and described herein, in any suitable order, including simultaneous performance of suitable groups of operations as appropriate. Included in the scope of the present disclosure, inter alia, are machine-readable instructions for performing any or all of the operations of any of the methods shown and described herein, in any suitable order; program storage devices readable by machine, tangibly embodying a program of instructions executable by the machine to perform any or all of the operations of any of the methods shown and described herein, in any suitable order i.e., not necessarily as shown, including performing various operations in parallel or concurrently, rather than sequentially as shown; a computer program product comprising a computer useable medium having computer readable program code, such as executable code, having embodied therein, and/or including computer readable program code for performing any or all of the operations of any of the methods shown and described herein, in any suitable order; any technical effects brought about by any or all of the operations of any of the methods shown and described herein, when performed in any suitable order; any suitable apparatus or device or combination of such, programmed to perform, alone or in combination, any or all of the operations of any of the methods shown and described herein, in any suitable order; electronic devices, each including at least one processor and/or cooperating input device and/or output device and operative to perform, e.g., in software, any operations shown and described herein; information storage devices or physical records, such as disks or hard drives, causing at least one computer or other device to be configured so as to carry out any or all of the operations of any of the methods shown and described herein, in any suitable order; at least one program pre-stored e.g. in memory or on an information network such as the Internet, before or after being downloaded, which embodies any or all of the operations of any of the methods shown and described herein, in any suitable order, and the method of uploading or downloading such, and a system including server/s and/or client/s for using such; at least one processor configured to perform any combination of the described operations or to execute any combination of the described modules; and hardware which performs any or all of the operations of any of the methods shown and described herein, in any suitable order, either alone or in conjunction with software. Any computer-readable or machine-readable media described herein is intended to include non-transitory computer-or machine-readable media.

Any computations or other forms of analysis described herein may be performed by a suitable computerized method. Any operation or functionality described herein may be wholly or partially computer-implemented, e.g., by one or more processors. The invention shown and described herein may include (a) using a computerized method to identify a solution to any of the problems or for any of the objectives described herein, the solution optionally including at least one of a decision, an action, a product, a service, or any other information described herein, that impacts, in a positive manner, a problem or objectives described herein; and (b) outputting the solution.

The system may, if desired, be implemented as a network, e.g., web-based system employing software, computers, routers, and telecommunications equipment, as appropriate.

Any suitable deployment may be employed to provide functionalities, e.g., software functionalities shown and described herein. For example, a server may store certain applications, for download to clients, which are executed at the client side, the server side serving only as a storehouse. Any or all functionalities, e.g., software functionalities shown and described herein, may be deployed in a cloud environment. Clients, e.g., mobile communication devices such as smartphones, may be operatively associated with, but external to the cloud.

The scope of the present invention is not limited to structures and functions specifically described herein, and is also intended to include devices which have the capacity to yield a structure, or perform a function, described herein, such that even though users of the device may not use the capacity, they are, if they so desire, able to modify the device to obtain the structure or function.

Any “if-then” logic described herein is intended to include embodiments in which a processor is programmed to repeatedly determine whether condition x, which is sometimes true and sometimes false, is currently true or false, and to perform y each time x is determined to be true, thereby to yield a processor which performs y at least once, typically on an “if and only if” basis, e.g., triggered only by determinations that x is true, and never by determinations that x is false.

Any determination of a state or condition described herein, and/or other data generated herein, may be harnessed for any suitable technical effect. For example, the determination may be transmitted or fed to any suitable hardware, firmware, or software module, which is known or which is described herein to have capabilities to perform a technical operation responsive to the state or condition. The technical operation may, for example, comprise changing the state or condition, or may more generally cause any outcome which is technically advantageous given the state or condition or data, and/or may prevent at least one outcome which is disadvantageous, given the state or condition or data. Alternatively, or in addition, an alert may be provided to an appropriate human operator or to an appropriate external system.

Features of the present invention, including operations, which are described in the context of separate embodiments, may also be provided in combination in a single embodiment. For example, a system embodiment is intended to include a corresponding process embodiment, and vice versa. Also, each system embodiment is intended to include a server-centered “view” or client centered “view”, or “view” from any other node of the system, of the entire functionality of the system, computer-readable medium, apparatus, including only those functionalities performed at that server or client or node. Features may also be combined with features known in the art, and particularly, although not limited to those described in the Background section or in publications mentioned therein.

Conversely, features of the invention, including operations, which are described for brevity in the context of a single embodiment or in a certain order, may be provided separately or in any suitable sub-combination, including with features known in the art (particularly. although not limited to, those described in the Background section, or in publications mentioned therein) or in a different order. “e.g.” is used herein in the sense of a specific example which is not intended to be limiting. Each method may comprise all or any subset of the operations illustrated or described, suitably ordered, e.g., as illustrated or described herein.

Devices, apparatus, or systems shown coupled in any of the drawings, may in fact be integrated into a single platform in certain embodiments, or may be coupled via any appropriate wired or wireless coupling, such as but not limited to optical fiber, Ethernet, Wireless LAN, HomePNA, power line communication, cell phone, Smart Phone (e.g. iPhone), Tablet, Laptop, PDA, Blackberry GPRS, Satellite including GPS, or other mobile delivery. It is appreciated that in the description and drawings shown and described herein, functionalities described or illustrated as systems and sub-units thereof, can also be provided as methods and operations therewithin, and functionalities described or illustrated as methods and operations therewithin can also be provided as systems and sub-units thereof. The scale used to illustrate various elements in the drawings is merely exemplary and/or appropriate for clarity of presentation, and is not intended to be limiting.

Any suitable communication may be employed between separate units herein e.g. wired data communication and/or in short-range radio communication with sensors such as cameras e.g., via Wifi, Bluetooth, or Zigbee.

It is appreciated that implementation via a cellular app as described herein, is but an example, and, instead, embodiments of the present invention may be implemented, say, as a smartphone SDK, as a hardware component, as an STK application, or as suitable combinations of any of the above.

Any processing functionality illustrated (or described herein) may be executed by any device having a processor, such as but not limited to a mobile telephone, set-top-box, TV, remote desktop computer, game console, tablet, mobile e.g. laptop or other computer terminal, embedded remote unit, which may either be networked itself (may itself be a node in a conventional communication network e.g.) or may be conventionally tethered to a networked device (to a device which is a node in a conventional communication network, or is tethered directly or indirectly/ultimately to such a node).

Any operation or characteristic described herein may be performed by another actor outside the scope of the patent application, and the description is intended to include apparatus, whether hardware, firmware, or software which is configured to perform, enable, or facilitate that operation, or to enable, facilitate, or provide that characteristic.

The terms processor or controller or module or logic, as used herein, are intended to include hardware such as computer microprocessors or hardware processors, which typically have digital memory and processing capacity, such as those available from, say Intel and Advanced Micro Devices (AMD). Any operation, or functionality, or computation, or logic described herein, may be implemented entirely or in any part on any suitable circuitry, including any such computer microprocessor/s, as well as in firmware or in hardware, or any combination thereof.

It is appreciated that elements illustrated in more than one drawing, and/or elements in the written description may still be combined into a single embodiment, except if otherwise specifically clarified herewithin. Any of the systems shown and described herein may be used to implement or may be combined with, any of the operations or methods shown and described herein.

It is appreciated that any features, properties, logic, modules, blocks, operations, or functionalities described herein which are, for clarity, described in the context of separate embodiments, may also be provided in combination in a single embodiment, except where the specification or general knowledge specifically indicates that certain teachings are mutually contradictory, and cannot be combined. Any of the systems shown and described herein may be used to implement or may be combined with, any of the operations or methods shown and described herein.

Conversely, any modules, blocks, operations, or functionalities described herein, which are, for brevity, described in the context of a single embodiment, may also be provided separately or in any suitable sub-combination, including with features known in the art. Each element, e.g., operation described herein, may have all characteristics and attributes described or illustrated herein, or, according to other embodiments, may have any subset of the characteristics or attributes described herein.

References herein to “said (or the) element x” having certain (e.g., functional or relational) limitations/characteristics, are not intended to imply that a single instance of element x is necessarily characterized by all the limitations/characteristics. Instead, “said (or the) element x” having certain (e.g., functional or relational) limitations/characteristics, is intended to include both (a) an embodiment in which a single instance of element x is characterized by all of the limitations/characteristics and (b) embodiments in which plural instances of element x are provided, and each of the limitations/characteristics is satisfied by at least one instance of element x, but no single instance of element x satisfies all limitations/characteristics. For example, each time L limitations/characteristics are ascribed to “said” or “the” element X in the specification or claims (e.g. to “said processor” or “the processor”), this is intended to include an embodiment in which L instances of element X are provided, which respectively satisfy the L limitations/characteristics, each of the L instances of element X satisfying an individual one of the L limitations/characteristics. The plural instances of element x need not be identical. For example, if element x is a hardware processor, there may be different instances of x, each programmed for different functions and/or having different hardware configurations (e.g., there may be 3 instances of x: two Intel processors of different models, and one AMD processor).

1.-23. (canceled)

24. A method for controlling an industrial process in a factory, the industrial process involving a flow of material, the method comprising using a hardware processor for:
accepting a definition and/or information regarding a route extending from a source (e.g., raw material tank) to a destination (e.g., filler), along which the material flows;
and, accordingly, automatically activating and/or de-activating material flow along the route.

25. The method according to claim 24, wherein said automatically activating and de-activating comprises:
grouping the elements into group/s (aka sequencing groups) thereby to facilitate route activation and deactivation; and
automatically generating source code (e.g. PLC code) for controllers (e.g., Programmable Logic Controllers) which control sequencing groups of elements (e.g. valves, conveyor transfers, pumps) along the route, wherein the source code orchestrates or controls the route (e.g., causing material to flow along the route), wherein the source code, when executed by the controllers, is configured to:
a. close, or ensure closure of, all controlled elements, e.g., valves (“junction valves”), conveyor transfers along the route which enable material to flow in any direction other than along the route; and
b. open valves and shifters downstream of a first group of engines, and then, subsequently, activate all valves and conveyor transfers between the source and the first group of engines, and then, subsequently, activate the first group of engines wherein within each sequencing group, wherein engines are activated in an upstream direction such that given a first engine in the group which is upstream of a second engine in the group, the first engine is activated only after the second engine is activated.

26. The method according to claim 25, wherein multiple engines exist along the route including a last engine which is downstream of all other engines along the route and where a sequencing group downstream of the last engine is activated first, then a sequencing group upstream of the first engine, and only then a sequencing group that includes the engines.

27. The method according to claim 25, wherein deactivation of a route occurs in an order which is reversed relative to the order in which activation of the route occurs, including:
deactivating elements within each group in an order which is reversed relative to an order in which the elements within said group were activated such that an element x in a Group A which was activated before an element y in said Group A, is deactivated after element y is deactivated, and
deactivating groups in an order which is reversed relative to an order in which said groups were activated such that a Group A, which was activated before Group B, is deactivated after Group B is deactivated.

28. The method according to claim 24, wherein the source code provides a sequencing order of all valves along the route.

29. The method according to claim 24, wherein the source code provides a sequencing order of all pumps along the route.

30. The method according to claim 24, wherein the source code provides a sequencing order of all motors along the route.

31. The method according to claim 24, wherein the source code provides a sequencing order of all conveyers along the route.

32. The method according to claim 24, utilizing start criteria and/or stop criteria which are static.

33. The method according to claim 24, wherein material flows along the route through pipes and/or via conveyers.

34. The method according to claim 32, wherein at least one of said start criteria and/or stop criteria which are static comprises a duration criterion.

35. The method according to claim 24, wherein said accepting the definition includes automated analysis configured to identify any engines (e.g., conveyers, motors, pumps) that drive material flow along the route.

36. The method according to claim 24, wherein said source comprises a raw material tank, and said destination comprises a filler.

37. The method according to claim 25, wherein said engines are taken from a group comprising at least conveyers, motors, and pumps.

38. The method according to claim 24, wherein the method includes automated analysis of
all controlled elements along the route; and
the controlled elements' sequential arrangement along the route, to determine a set of control actions and status verifications to yield safe activation and/or safe deactivation of material flow through the route.

39. The method according claim 24, also comprising allowing authorized users, designated from among factory personnel or system integrators, to make modifications to specific routing and sequencing parameters to optimize or recover production issues without PLC downtime.

40. The method according to claim 24, wherein said given operation comprises in-unit operation taking place within a single element participating in the given operation.

41. The method according to claim 24, wherein said code is configured for issuing commands which activate and de-activate each element along the route, typically while taking care of any alarm being flagged (typically all commands necessary).

42. The method according to claim 24, wherein said code is configured to cause the route's status, including operational parameters' real time present values, to be displayed to an operator.

43. The method according to claim 25, wherein all of said junction valves are verified as closed simultaneously.

44. The method according to claim 25, wherein all engines in the first group are activated simultaneously.

45. A hardware processor configured to perform the method of claim 24.

46. A computer program product, comprising a non-transitory tangible computer readable medium having computer readable program code embodied therein,
said computer readable program code adapted to be executed to implement a method for controlling an industrial process in a factory, the industrial process involving a flow of material,
the method comprising:
accepting a definition and/or information regarding a route extending from a source (e.g., raw material tank) to a destination (e.g., filler), along which the material flows; and, accordingly,
automatically activating and/or de-activating material flow along the route.
